(19) United States
(12) Patent Application Publication
(10) Pub. No.: US 2025/0350260 A1
(43) Pub. Date: Nov. 13, 2025

(54) IDT-EXCITED ACOUSTIC RESONATOR WITH HIGH COUPLING AND LOW TCF

(71) Applicant: Qorvo US, Inc., Greensboro, NC (US)

(72) Inventors: Jason McGann, Tavares, FL (US); Marc Solal, Longwood, FL (US); Patrik Rath, Schwaebisch Gmuend (DE)

(21) Appl. No.: 19/184,060

(22) Filed: Apr. 21, 2025

Related U.S. Application Data
(60) Provisional application No. 63/645,412, filed on May 10, 2024.

(51) Int. Cl. H03H 9/25; H03H 9/02

(52) U.S. Cl. CPC H03H 9/25; H03H 9/02551; H03H 9/02834; H03H 9/02992

(57) ABSTRACT

An acoustic resonator includes a substrate, a lithium tantalate layer disposed over the substrate, and a transducer on the lithium tantalate layer. The lithium tantalate layer has a crystalline orientation defined by a first Euler angle (λ), a second Euler angle (μ), and a third Euler angle (θ), and the first Euler angle (λ), the second Euler angle (μ), and the third Euler angle (θ) are chosen such that an acoustic plate mode (APM) is a dominant mode excited in the acoustic resonator.

### CROSS-REFERENCE TO RELATED APPLICATIONS

The present application claims the benefit of U.S. Provisional Application No. 63/645,412, entitled “IDT-EXCITED ACOUSTIC RESONATOR WITH HIGH COUPLING AND LOW TCF” and filed on May 10, 2024, which is incorporated herein by reference in its entirety.

### FIELD OF THE DISCLOSURE

The technology disclosed herein relates generally to acoustic wave devices, and in particular to acoustic resonators excited by an interdigital transducer (IDT) with piezoelectric materials oriented in crystalline directions configured to improve performance of coupling, frequency, and temperature coefficient of frequency (TCF).

### BACKGROUND

Acoustic wave devices are widely used in modern electronics. At a high level, acoustic wave devices include a piezoelectric material in contact with one or more electrodes. Piezoelectric materials acquire a charge when compressed, twisted, or distorted, and similarly compress, twist, or distort when a charge is applied to them. Accordingly, when an alternating electrical signal is applied to the one or more electrodes in contact with the piezoelectric material, a corresponding mechanical signal (i.e., an oscillation or vibration) is transduced therein. Based on the characteristics of the one or more electrodes on the piezoelectric material, the properties of the piezoelectric material, and other factors such as the shape of the acoustic wave device and other structures provided on the device, the mechanical signal transduced in the piezoelectric material exhibits a frequency dependence on the alternating electrical signal. Acoustic wave devices leverage this frequency dependence to provide one or more functions.

Exemplary acoustic wave devices include surface acoustic wave (SAW) resonators, which are increasingly used to form filters used in the transmission and reception of RF signals for communication. In SAW resonators, an electrode pitch of an interdigital transducer (IDT) primarily defines a center frequency of the resonators. The escalating demands of modern RF communication systems necessitate that acoustic wave devices offer increasingly compact form factors. This entails achieving higher center frequencies by further reducing an electrode pitch of an IDT. However, the minimal achievable Critical Dimension (CD) of an IDT is constrained by existing fabrication methods, such as Deep Ultraviolet (DUV) lithography. Traditional SAW resonators have reached a development bottleneck in further minimizing the CD of an IDT and increasing the center frequency without significant advancements in lithography technology. Consequently, this opens up opportunities for innovative approaches in the realm of acoustic wave devices beyond the conventional SAW resonators.

### SUMMARY

Example aspects of the present disclosure provide an IDT-excited acoustic resonator with a piezoelectric layer oriented in a particular crystalline direction. The particular crystalline direction of the piezoelectric layer allows an acoustic plate mode (APM) to be excited in the acoustic resonator, which is different from the surface acoustic wave (SAW) mode excited in conventional SAW resonators. An acoustic resonator operating under APM exhibits a much higher center frequency than a conventional SAW resonator, as the center frequency is no longer primarily determined by an electrode pitch of an IDT but by the thickness of the piezoelectric layer. Stated differently, the center frequency of an acoustic resonator operating under APM is not primarily constrained by limits of existing fabrication methods. Such an acoustic resonator operating under APM can be termed as an APM resonator to differentiate from a SAW resonator.

Due to the stringent demands placed on filters for modern RF communication systems, acoustic wave devices for these applications must provide high quality factor, low loss, wide bandwidth (i.e., high electromechanical coupling coefficient), and favorable temperature coefficient of frequency (TCF). Further, as modern RF communication systems utilize an increasing number of RF communication bands and aggregate bandwidth for improved throughput, it is desirable for acoustic wave devices for these applications to have a high bandwidth. Embodiments of the present disclosure provides APM resonators with high coupling, favorable TCF, high quality factor, low loss, and high bandwidth.

In one embodiment, an acoustic resonator includes a substrate, a lithium tantalate layer disposed over the substrate, and a transducer on the lithium tantalate layer. The lithium tantalate layer has a crystalline orientation defined by a first Euler angle (λ), a second Euler angle (μ), and a third Euler angle (θ), and the first Euler angle (λ), the second Euler angle (μ), and the third Euler angle (θ) are chosen such that an acoustic plate mode (APM) is a dominant mode excited in the acoustic resonator.

In another embodiment, an acoustic resonator includes a substrate, a piezoelectric crystal disposed over the substrate, and an interdigital transducer on the piezoelectric crystal. The piezoelectric crystal has a crystalline orientation defined by a first Euler angle (λ), a second Euler angle (μ), and a third Euler angle (θ), and the second Euler angle (μ) ranges from about −60° to about +30°.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description, serve to explain the principles of the disclosure.

FIG. 1 illustrates a perspective view of a conventional acoustic resonator.

FIG. 2 is a graph illustrating the operation of an ideal acoustic resonator.

FIG. 3 is an admittance plot comparing an SAW resonator and an APM resonator with the same electrode pitch, according to some aspects of the present disclosure.

FIG. 4 illustrates the description of crystalline orientations of a material layer, according to some aspects of the present disclosure.

FIGS. 5A and 5B illustrate cross-sectional views of exemplary APM resonators, according to some aspects of the present disclosure.

FIG. 6 illustrates the APM displacement in an exemplary APM resonator, according to some aspects of the present disclosure.

FIGS. 7, 8, 9, 10, 11, 12, 13, and 14 are graphs illustrating the simulated performance of exemplary APM resonators, according to various embodiments of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

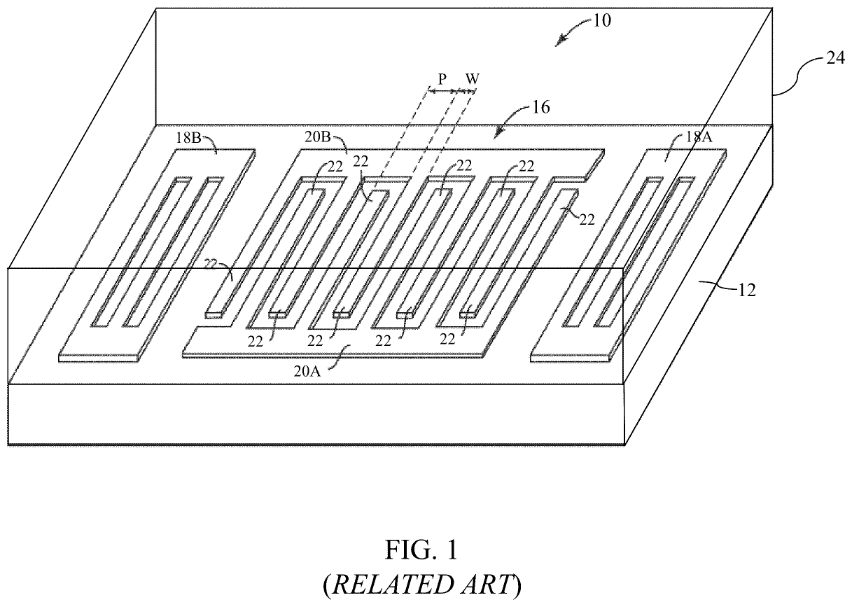

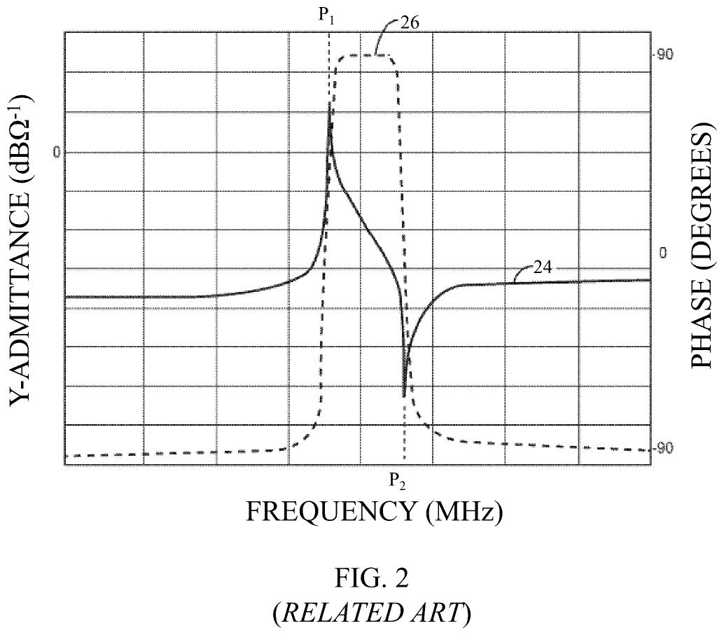

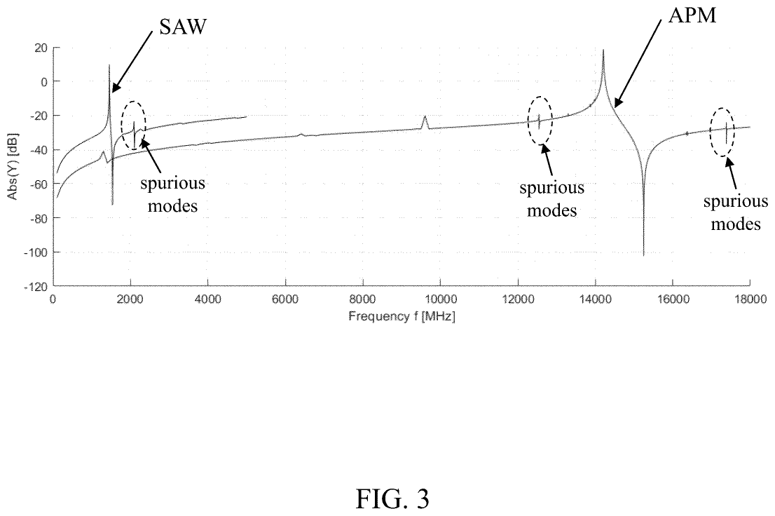

Before addressing exemplary aspects of the present disclosure, a brief discussion of a conventional approach to an acoustic resonator and its limitations is provided with reference to FIGS. 1 and 2. A discussion of exemplary aspects of the present disclosure begins below with reference to FIG. 3.

FIG. 1 shows a perspective view of a conventional acoustic resonator 10, particularly a surface acoustic wave (SAW) resonator. The acoustic resonator 10 includes a piezoelectric substrate 12, an interdigital transducer 16 on a surface of the piezoelectric substrate 12, a first reflector structure 18A on the surface of the piezoelectric substrate 12 adjacent to the interdigital transducer 16, and a second reflector structure 18B on the surface of the piezoelectric substrate 12 adjacent to the interdigital transducer 16 opposite the first reflector structure 18A. the acoustic resonator 10 also includes a dielectric overcoat 24 with a positive TCF, in a form of a silicon oxide layer disposed over the interdigital transducer 16. In some embodiments, the piezoelectric substrate 12 is a single crystal piezoelectric substrate. In furtherance of some embodiments, the piezoelectric substrate 12 is a single crystal lithium niobate (LN) substrate or a single crystal lithium tantalate (LT) substrate.

The interdigital transducer 16 includes a first comb electrode 20A and a second comb electrode 20B, each of which includes a number of electrode fingers 22 that are interleaved with one another as shown. A lateral distance between adjacent electrode fingers 22 of the first comb electrode 20A and the second comb electrode 20B defines an electrode pitch P of the interdigital transducer 16. The electrode pitch P may at least partially define a center frequency wavelength λ of the acoustic resonator 10, where the center frequency is the primary frequency of mechanical waves generated in the piezoelectric layer 14 by the interdigital transducer 16. For a single electrode interdigital transducer 16 such as the one shown in FIG. 1, the center frequency wavelength λ is equal to twice the electrode pitch P. For a double electrode interdigital transducer 16, the center frequency wavelength λ is equal to four times the electrode pitch P. A finger width W of the adjacent electrode fingers 22 over the electrode pitch P may define a metallization ratio M of the interdigital transducer 16, which may dictate certain operating characteristics of the acoustic resonator 10.

In operation, an alternating electrical input voltage provided between the first comb electrode 20A and the second comb electrode 20B is transduced into a mechanical signal in the piezoelectric layer 14, resulting in one or more acoustic waves therein. In the case of the SAW resonator, the resulting acoustic waves are predominately surface acoustic waves. As discussed above, due to the electrode pitch P and the metallization ratio M of the interdigital transducer 16, the characteristics of the material of the piezoelectric layer 14, and other factors, the magnitude and frequency of the acoustic waves transduced in the piezoelectric layer 14 are dependent on the frequency of the alternating electrical input signal. This frequency dependence is often described in terms of changes in amplitude and phase of the impedance seen between the first comb electrode 20A and the second comb electrode 20B with respect to the frequency of the alternating electrical input signal. The acoustic waves transduced by the alternating electrical input signal travel in the piezoelectric layer 14, eventually being transduced back into an alternating electrical output signal. The first reflector structure 18A and the second reflector structure 18B reflect the acoustic waves in the piezoelectric layer 14 back towards the interdigital transducer 16 to confine the acoustic waves in the area surrounding the interdigital transducer 16.

FIG. 2 is a graph illustrating an ideal relationship of the impedance (shown as the admittance amplitude) and impedance phase between the first comb electrode 20A and the second comb electrode 20B to the frequency of the alternating electrical input signal for the acoustic resonator 10. A solid line 24 illustrates the admittance amplitude between the first comb electrode 20A and the second comb electrode 20B with respect to the frequency of the alternating electrical input signal. Notably, the solid line 24 includes a peak at a first point P1 at which the admittance between the first comb electrode 20A and the second comb electrode 20B climbs rapidly to a maximum value. This peak occurs at the series resonant frequency (f_{S}) of the acoustic resonator 10. The impedance between the first comb electrode 20A and the second comb electrode 20B is minimal at the series resonant frequency (f_{S}), such that the first comb electrode 20A and the second comb electrode 20B appear as a short-circuit. The solid line 24 also includes a valley at a second point P2 at which the admittance between the first comb electrode 20A and the second comb electrode 20B plummets rapidly to a minimum value. This valley occurs at the parallel resonant frequency (f_{P}) of the acoustic resonator 10. The impedance between the first comb electrode 20A and the second comb electrode 20B is at a maximum at the parallel resonant frequency (f_{P}), such that the first comb electrode 20A and the second comb electrode 20B appear as an open circuit.

A dashed line 26 illustrates the phase of the impedance between the first comb electrode 20A and the second comb electrode 20B with respect to the frequency of the alternating electrical input signal. Notably, the dashed line shows that a 90° phase shift occurs between the series resonant frequency (f_{S}) and the parallel resonant frequency (f_{P}). This phase shift is due to the change in the impedance from primarily capacitive to primarily inductive between the series resonant frequency (f_{S}) and the parallel resonant frequency (f_{P}).

The graph shown in FIG. 2 is highly idealized. In reality, the response of the acoustic resonator 10 includes spurious areas that degrade the performance thereof as discussed above. In an effort to idealize the response of the acoustic resonator, several parameters of the device may be changed, such as the thickness of the metal for the interdigital transducer 16 and the reflector structures 18, the arrangement of the interdigital transducer 16 (i.e., the electrode pitch P and the finger width W), the material of the piezoelectric layer 14, the thickness of the piezoelectric layer 14, the crystalline orientation of the piezoelectric layer 14, the material of the substrate 12, and the crystalline orientation of the substrate 12. Changing each of these parameters may affect the performance of the guided acoustic wave device 10 in several ways. For example, reducing the electrode pitch P would shift the series resonant frequency (f_{S}) and the parallel resonant frequency (f_{P}) to a higher frequency band in the context of a conventional SAW resonator. However, the minimal achievable electrode pitch P is constrained by existing fabrication methods, such as Deep Ultraviolet (DUV) lithography. Conventional SAW resonators have reached a bottleneck in further minimizing the critical dimension (CD) of device features without significant advancements in lithography technology.

Due to improved wafer bonding technologies combined with wafer grinding or ion slicing, it is now possible to make thin single crystal lithium tantalate (LT) films with nearly arbitrary crystal orientations. The inventors have discovered that a film of lithium tantalate with certain crystalline orientation is suitable for exciting an acoustic plate mode (APM) as a dominant mode in an acoustic resonator other than a conventional surface acoustic wave (SAW) mode. The operating frequency of an acoustic resonator under APM is not constrained by the electrode pitch P of the interdigital transducer, which allows an acoustic resonator at the same form factor to work in a much higher frequency band. Such an acoustic resonator operating under APM is termed as an APM resonator in the present disclosure to differentiate from a SAW resonator. A comparison between an APM resonator and a SAW resonator is illustrated in FIG. 3. FIG. 3 illustrates admittance plots of the two acoustic resonators with the same electrode pitch of 1.3 um (P=1.3 um) but under two different acoustic wave modes—one under the conventional SAW mode and another under APM. For the acoustic resonator with the 1.3 um electrode pitch operating under the conventional SAW mode, the center frequency is about 1.4 GHz. For the acoustic resonator with the same 1.3 um electrode pitch operating under APM, the center frequency is about 14 GHz. The center frequency is shifted up for about 10 times without modifying the electrode pitch.

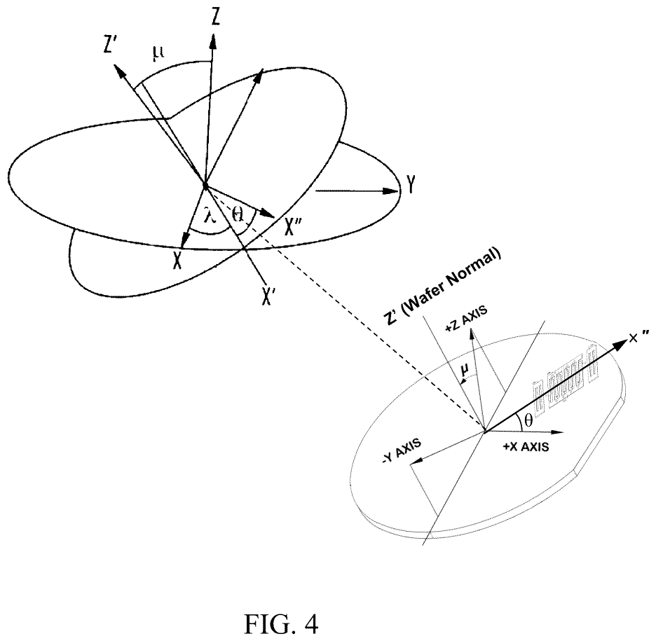

As further discussed below, a lithium tantalate film with certain crystalline orientation as the piezoelectric layer is suitable for exciting APM as the dominant mode in an APM resonator. Referring to FIG. 4, one way to describe the rotational orientation of wafers cut for crystals is using Euler angles. According to Euler's description, any rotations are defined by three Euler angles. Although there are several different notational conventions, in this work x-convention is used. In the x-convention, the first Euler angle is referred to as lambda (λ), the second Euler angle is referred to as mu (μ), and the third Euler angle is referred to as theta (θ). Specifically, the rotation is given by Euler angles (λ, μ, θ), where the first rotation is by an angle λ about the z-axis, the second is by an angle μ about the x-axis, and the third is by an angle θ about the z-axis again. The surface of the wafer is defined by the x-y plane corresponding to the third rotation with the direction of propagation in the direction specified by the third angle θ. The description of the present invention also refers to rotational orientation of the wafers cut from the crystals as Y-rotated and X-propagating. This description involves only a single rotation, ψ. The equivalent Euler angles are (λ=0, μ=90−ψ, θ=0).

By way of explanation regarding the angle convention herein used to describe crystal orientations, consider an orientation procedure defining a substrate cut and propagation direction of a SAW device within this cut according to the specified Euler angles (λ, μ, θ). With initial coordinate axes X, Y, Z fixed along crystal axes of a crystal substrate according to the Euler angle convention, first, auxiliary axis X′ (positive direction) is obtained by rotation from positive X axis towards positive Y axis by the angle λ. The outward normal to the substrate cut Z′ is then found by rotation about auxiliary axis X′ from positive Z axis, by the angle μ counter-clockwise, as viewed from positive X′. Finally, the direction of surface wave propagation X″ on propagation surface is found by rotation about Z′ from positive X′ axis by the angle θ counterclockwise, as viewed from positive Z′ axis. Reference is also made to U.S. Pat. Nos. 6,661,313 and 6,556,104 describing SAW devices using optimum cuts of piezoelectric substrates, the disclosures of which are herein incorporated by reference in their entirety.

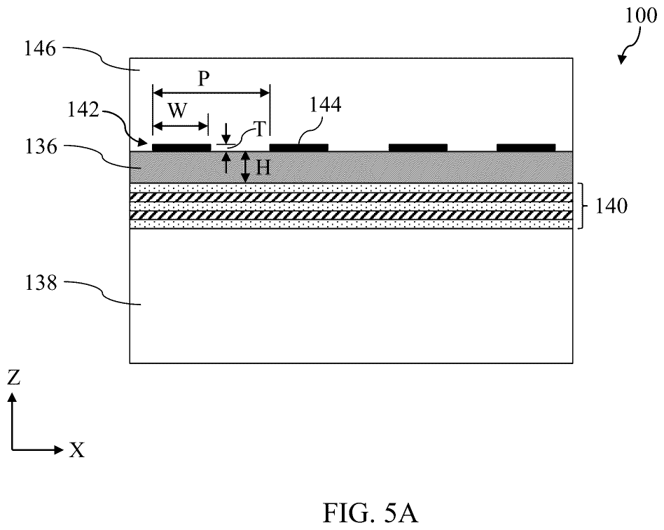

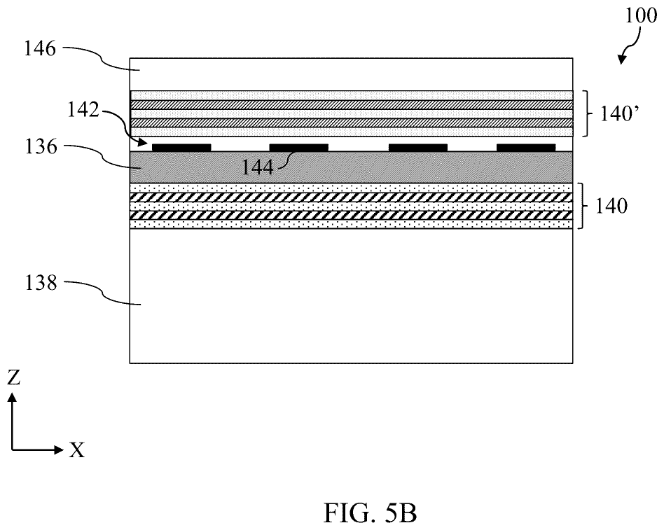

One example of an APM resonator 100 including a piezoelectric layer, or film, 136 bonded or deposited on a carrier substrate 138 is illustrated in FIG. 5A. The choice of the piezoelectric layer 136 for the APM resonator 100 is critical for exciting an acoustic wave in APM as the dominant mode. In the illustrated embodiment, the piezoelectric layer is a lithium tantalate film with the second Euler angle mu (μ) in the range from about −60° to about 30°. For example, the piezoelectric layer is a lithium tantalate film with the second Euler angle mu (μ) between about −92° and about −72° (−92°≤μ≤−72°). The first Euler angle lambda (λ) is about 0° (λ≈0°). The third Euler angle theta (θ) range from about 0° to about 90°. In one particular example, the third Euler angle theta (θ) is about 45°. Notably, present disclosure also contemplates angles under equivalent orientations. For example, in the XY plane, the transducer aiming at the X direction is the same as aiming at the −X direction. A thickness H of the piezoelectric layer is between about 0.1 μm to about 1.1 um for the excitation of resonant modes at the RF bands. A conventional SAW resonator would not consider using such a small thickness H. This is because the resonant modes to be excited are very different. The choice of these ranges for the Euler angles (λ, μ, θ) and the thickness H as a combo is not trivial or arbitrary but critical for the performance of the device. On such a piezoelectric layer, the acoustic resonator is excited primarily APM waves. The mechanical displacement associated with these waves is primarily in the direction parallel to the electrodes. The advantage of APM waves is to produce a center frequency primarily determined by the piezoelectric layer thickness instead of an electrode pitch, tether with a large electroacoustic coupling and a relatively good temperature stability of the device frequency. Similarly, it is also possible to replace lithium tantalate with lithium niobate (LN). In this case, the same type of acoustic wave is excited. A large coupling coefficient can be obtained with a relatively good temperature stability of the device frequency.

Still referring to FIG. 5A, the APM resonator 100 also includes an acoustic Bragg reflector 140 is sandwiched between the carrier substrate 138 and the piezoelectric layer 136. The term “sandwiched” means the acoustic Bragg reflector 140 is both disposed between and physically connected to a top surface of the substrate 138 and a bottom surface of the piezoelectric layer 136. In some circumstances, thin layers of additional materials may be disposed between the acoustic Bragg reflector 140 and the top surface of the substrate 138 and/or between the acoustic Bragg reflector 140 and the bottom surface of the piezoelectric layer 136. Such additional material layers may be present, for example, to facilitate bonding the piezoelectric layer 136, the acoustic Bragg reflector 140, and the substrate 138.

The acoustic Bragg reflector 140 includes multiple layers that alternate between materials having high acoustic impedance and materials have low acoustic impedance. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. Each of the layers has a thickness equal to, or about, one-fourth of the acoustic wavelength at or near a resonance frequency of the APM resonator 100. Materials having comparatively low acoustic impedance include silicon dioxide, silicon oxycarbide, aluminum, and certain plastics such as cross-linked polyphenylene polymers. Materials having comparatively high acoustic impedance include silicon nitride, aluminum nitride, silicon carbide, and metals such as molybdenum, tungsten, gold, and platinum. All of the high acoustic impedance layers of the acoustic Bragg reflector 140 are not necessarily the same material, and all of the low acoustic impedance layers are not necessarily the same material. In the example of FIG. 5A, the acoustic Bragg reflector 140 has a total of five layers. An acoustic Bragg reflector may have more than, or less than, five layers. In some embodiments, the acoustic Bragg reflector 140 may be omitted, such that the piezoelectric layer 136 is disposed on the carrier substrate 138.

The carrier substrate 138 may be, for example, silicon, sapphire, quartz, or some other material. A commonly used carrier substrate is one made of Si. One problem of Si is its conductivity, which results in losses by dielectric influence. The carrier substrate 138 is favorable to have the following properties: 1) The carrier substrate 138 has to be insulating. A metallic substrate produces a strong coupling between a filter input and output and adds a capacitance that reduces the electroacoustic coupling. A semiconductor substrate also produces some losses due to its conductivity. 2) The carrier substrate 138 needs to have a low permittivity to reduce the device capacitance and to increase the piezoelectric coupling. 3) The carrier substrate 138 needs to have low acoustic viscous losses, which can be obtained normally by using a monocrystalline substrate. 4) The TCF for the carrier substrate 138 should be small (in absolute value) and if possible have a sign opposite to that of the TCF of the piezoelectric layer 136, which is negative. Additionally, a low coefficient of thermal expansion is favorable. In some embodiments, the carrier substrate 138 is made of quartz. Quartz presents several advantages: 1) Quartz has a low dielectric constant of about 4.5. 2) Quartz is not a semiconductor, which means that its conductivity is very low. 3) Quartz has been extensively studied for acoustic resonators, and the quality of quartz has been enhanced to reduce viscous losses. For this reason, resonators with very good quality factors can be obtained using a piezoelectric layer on quartz. 4) From the point of view of thermal sensitivity, quartz has the advantage of a low temperature sensitivity and has compensated cuts for which the TCF is 0. As such, quartz is utilized as the material for the carrier substrate 138 of the APM resonator 100 in some embodiments.

A metal transducer, or IDT, 142 is disposed on a surface of the piezoelectric layer 136 opposite the carrier substrate 138. The IDT fingers 144 of the IDT 142 may be aluminum or a substantially aluminum alloy, copper or a substantially copper alloy, beryllium, gold, or some other conductive material with a thickness T. Thin (relative to the thickness T) layers of other metals, such as chromium or titanium, may be formed under and/or over the fingers to improve adhesion between the fingers and the piezoelectric layer 136 and/or to passivate or encapsulate the fingers. Dimension P is the edge-to-edge or center-to-center spacing or “pitch” of the IDT fingers, which may be referred to as the pitch of the IDT. A length of the IDT 142 along the X-direction may be more than 100 times of the pitches P. Dimension W is the width of the IDT fingers. A metallization ratio M of the finger width W over electrode pitch P ranges from about 0.25 to about 0.35 (0.25<W/P<0.35). With respect to the thickness H of the piezoelectric layer 136, a ratio of P/H is larger than 10 (P/H>10), and a ratio of H/T is larger than 10 (H/T>10). The ranges of these ratios are not trivial or arbitrary. One of the criticalities of keeping the ratios in the above ranges is to push the spurious modes (as denoted in FIG. 3) away from center frequency of the main mode. Optionally one or more dielectric layers 146 (e.g., one or more layers of SiO₂, which may in some embodiments be doped) on a surface of the metal transducer 142 and an exposed surface of the piezoelectric layer 136.

FIG. 5B illustrates another embodiment of the APM resonator 100. Many aspects of the embodiments in FIG. 5B are the same as in FIG. 5A. One difference is that the APM resonator 100 as depicted in FIG. 5B also includes an acoustic Bragg reflector 140′ above the IDT 142. The acoustic Bragg reflector 140′ may be identical to the acoustic Bragg reflector 140, such as the same alternately stacked material compositions and the same number of layers. Alternatively, the acoustic Bragg reflector 140′ may be different from the acoustic Bragg reflector 140, such as different material compositions for the high acoustic impedance material and the low acoustic impedance material, and/or different number of layers.

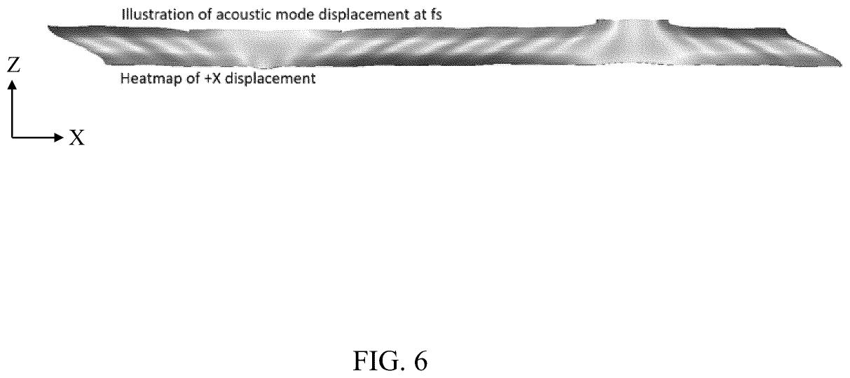

FIG. 6 shows the FEM simulation of displacement of the APM excited in the crystalline orientation of the piezoelectric layer 136 due to the particular arrangements of the first, second, third Euler angles. The FEM simulation of a periodic IDT structure with alternative polarity suggests that the acoustic mode shape consists of periodic repetitions of BAW-like modes. Along the X-direction, within a single IDT period, the wave vector is predominantly Z-directed, while displacements are predominantly X directed. The alternating polarity of the IDT gives rise to regions of compression and expansion in X-direction at the plate surfaces. Additionally, there appears to be a Y displacement component that has multiple periodic repetitions contained within a single IDT period that are “ribbon-like”. Unlike the illustrated APM, the displacement of the dominant modes as excited in conventional SAW and/or BAW resonators are in Y direction and homogeneous in Z-direction.

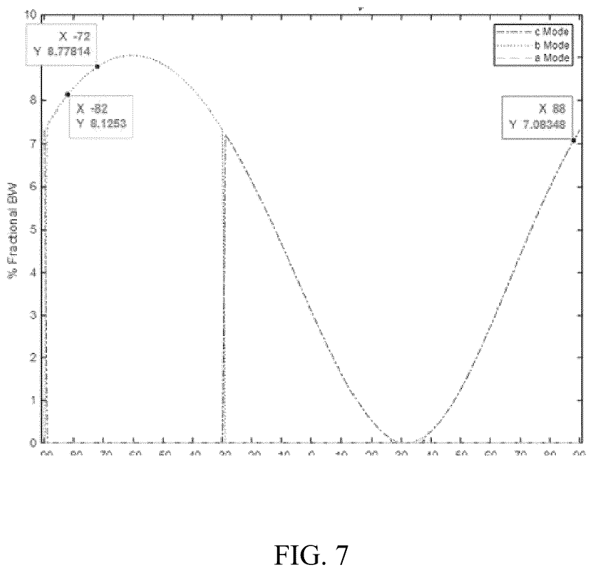

FIGS. 7-12 illustrate criticalities of the particular arrangements of the first, second, third Euler angles of the crystalline orientation of the piezoelectric layer 136 in safeguarding the resonator performance. Particularly, the variable for the plots in FIGS. 7-12 is the second Euler angle mu (μ).

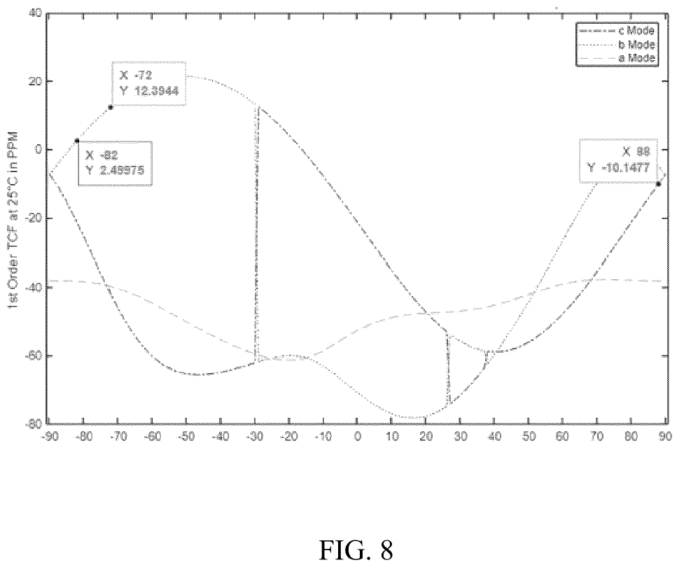

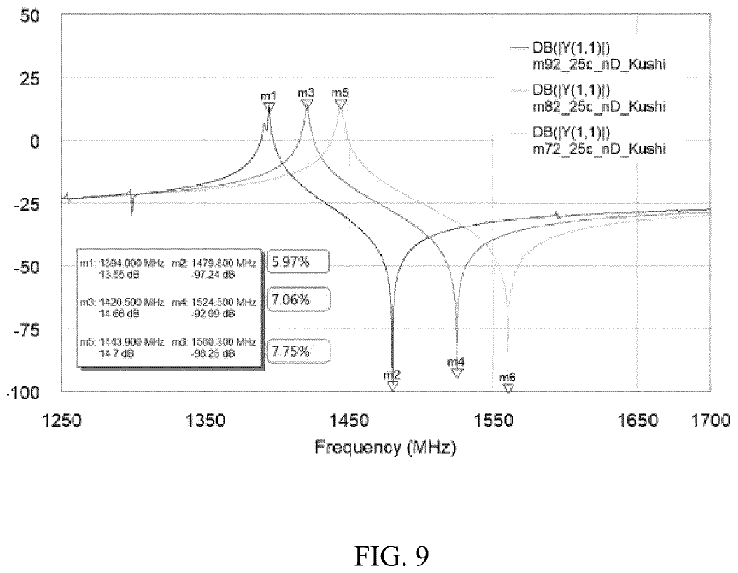

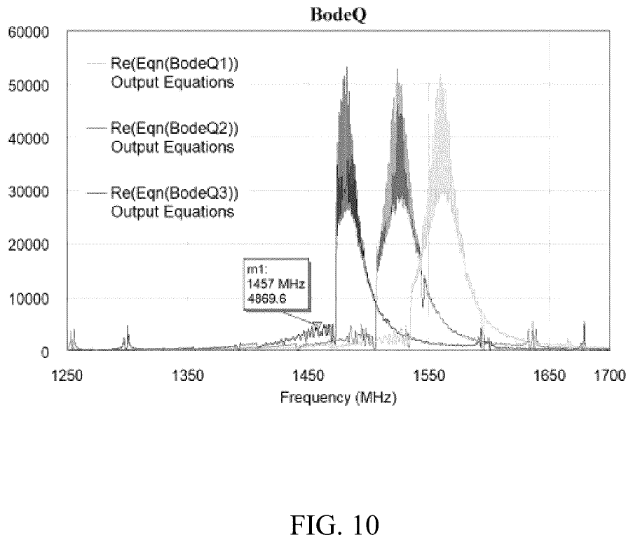

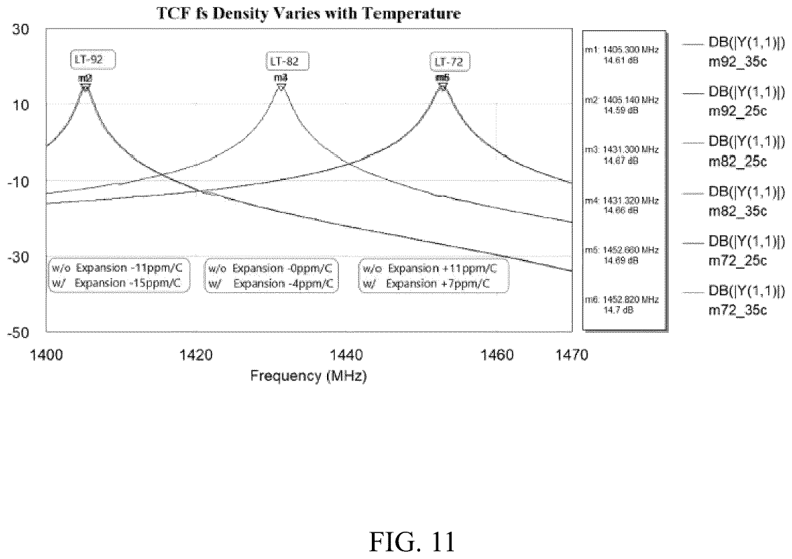

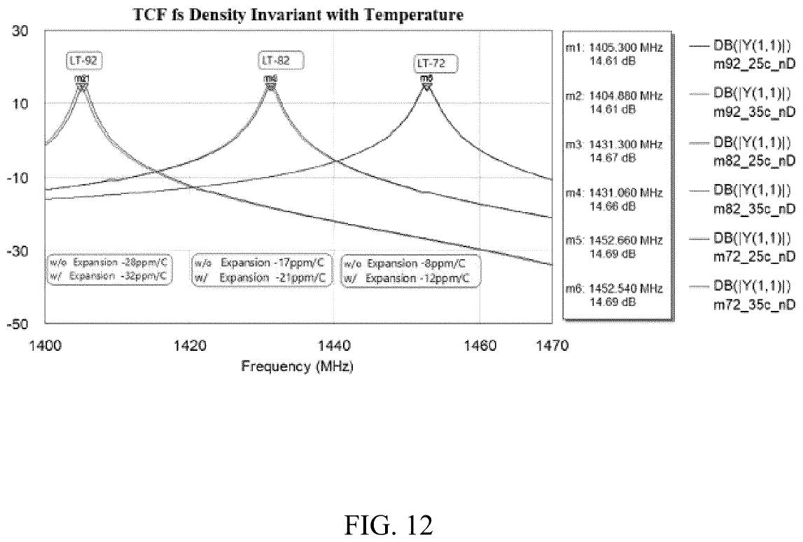

The orientation of the piezoelectric crystal can be optimized in order to provide both high coupling as well as a low temperature coefficient of frequency (TCF). FIG. 7 shows the fractional bandwidth of the APM. For the mode of interest, excited by a single pair of idealized electrodes, the resulting resonator fractional bandwidth (FBW) is computed from the series and parallel resonance, f_{S} and f_{P}, as 2 (f_{P}−f_{S})/(f_{P}+f_{S}). With the second Euler angle mu (μ) less than about −60° (μ<−60°), the APM resonator achieves a satisfying FBW. For example, when the second Euler angle mu (μ) is −72° (μ=72°), a large FBW of 8.78% is achieved; when the second Euler angle mu (μ) is −82° (μ=−82°), an FBW of 8.13% is achieved; and when the second Euler angle mu (μ) is −92° (μ=−92°), an FBW of 7.08% is achieved. FIG. 8 shows the 1^{st} order TCF of f_{S} at 25° C. based on a model where density and expansion vary with temperature. The piezoelectric crystal with the second Euler angle mu (μ) around −82° is expected to be optimal for achieving low TCF while simultaneously achieving high coupling to the APM of interest. FIG. 9 shows the magnitude of admittance for the APM resonator with an IDT of 200 pitches (or 100 electrode pairs) in length. The boundary conditions above and below the piezoelectric crystal are vacuum. The results show that the fractional bandwidth achieved varies from 6-8% fractionally, equivalent to a coupling coefficient of 13.5 to 17%, which is even higher than conventional LRT-SAW resonators. FIG. 10 shows the BodeQ curves for the APM resonator with an IDT of 200 pitches (or 100 electrode pairs) in length. The boundary conditions above and below the piezoelectric crystal are vacuum. The BodeQ at f_{P} appears to be limited only by the LT material loss parameters. Qp of about 20,000 and Qmax of about 40,000 are achieved while Qs is limited by ohmic losses in the IDT metal. FIG. 11 illustrates the TCF of f_{S} at 25° C. assuming that the bulk density of LT varies with temperature. Three cut angles, namely the second Euler angle mu (μ) at −72°, −82°, −92°, are depicted to illustrate that TCF at 25° C. may be readily controlled with cut angle adjustment. It is expected that small cut angle adjustments can be made to adjust the TCF inflection temperature to a target temperature to compensate for non-modeled effects. This effect is expected to result in filters that are extremely temperature stable with respect to IL and may also reduce thermal run-away effects under high power conditions. Similar to FIG. 11, FIG. 12 illustrates the TCF of f_{S} at 25° C. assuming that the bulk density of LT is invariant with temperature. Three cut angles, namely the second Euler angle mu (μ) at −72°, −82°, −92°, are depicted to illustrate that TCF may be readily controlled with cut angle adjustment. In the case that the LT wafer is bonded to an Si carrier wafer the LT bulk density may not vary significantly. In this case the TCF is expected to be negative at 25° C. but may be compensated instead with a layer of silicon dioxide.

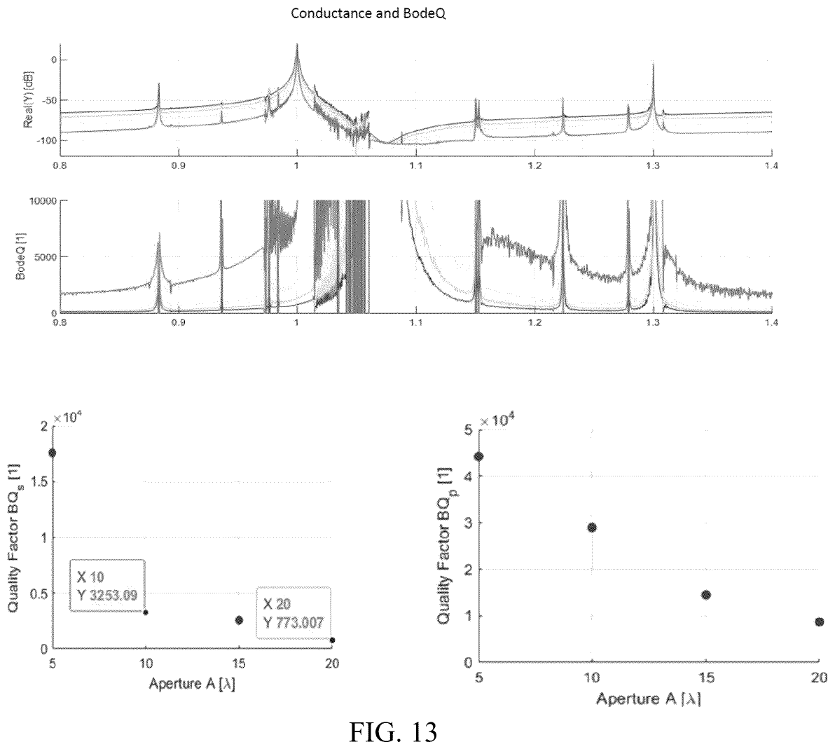

FIG. 13 shows the APM resonator conductance and BodeQ curves for resonator finite element simulations of devices that are varying in aperture. An aperture is the length of the IDT fingers in the Y-direction. As shown in FIG. 13, significant improvements in quality factors can be obtained by utilizing a resonator aperture of 5-10λ (or 10-20 electrode pitches). In some embodiments, for the APM resonator, an aperture of 5λ represents roughly 100 times of the thickness of the piezoelectric crystal.

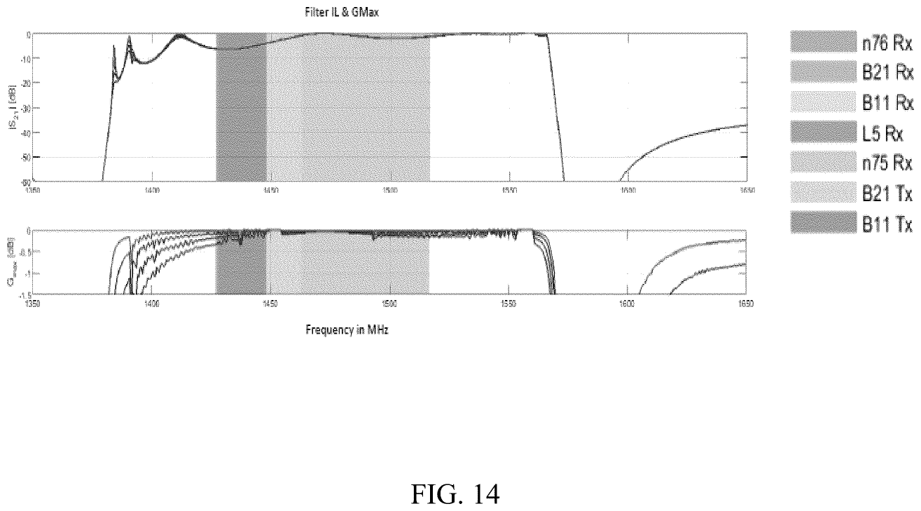

The APM resonators can be applied as building blocks for more complicated ladder filters. FIG. 14 shows insertion loss (IL) and maximum gain curves for exemplary ladder filters utilizing the APM resonators described in the present disclosure. As shown in FIG. 14, large fractional bandwidths can be achieved with steep transitions due to high resonator Qp for these APM based filters.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. An acoustic resonator, comprising:
a substrate;
a lithium tantalate layer disposed over the substrate; and
a transducer on the lithium tantalate layer,
wherein the lithium tantalate layer has a crystalline orientation defined by a first Euler angle (λ), a second Euler angle (μ), and a third Euler angle (θ), and wherein the first Euler angle (λ), the second Euler angle (μ), and the third Euler angle (θ) are chosen such that an acoustic plate mode (APM) is a dominant mode excited in the acoustic resonator.

2. The acoustic resonator of claim 1, wherein the second Euler angle (μ) is in a range from about −60° to about +30°.

3. The acoustic resonator of claim 1, wherein the second Euler angle (θ) is between −92° and −72°.

4. The acoustic resonator of claim 1, wherein the first Euler angle (λ) is about 0°, and the third Euler angle (θ) is in a range from about 0° to about 90°.

5. The acoustic resonator of claim 1, further comprising:
an acoustic Bragg reflector sandwiched between the substrate and the lithium tantalate layer.

6. The acoustic resonator of claim 1, wherein the transducer is an interdigital transducer comprising:
a first comb electrode comprising a first bus bar and a first plurality of electrode fingers extending transversely from the first bus bar; and
a second comb electrode comprising a second bus bar and a second plurality of electrode fingers extending transversely from the second bus bar such that:
the first bus bar is parallel to the second bus bar;
the first plurality of electrode fingers extend from the first bus bar towards the second bus bar;
the second plurality of electrode fingers extend from the second bus bar towards the first bus bar; and
the first plurality of electrode fingers are interleaved with the second plurality of electrode fingers.

7. The acoustic resonator of claim 6, wherein a ratio of a width of the electrode fingers over a pitch of the electrode fingers ranges from 0.25 to 0.35.

8. The acoustic resonator of claim 6, wherein a ratio of a pitch of the electrode fingers over a thickness of the lithium tantalate layer is larger than 10.

9. The acoustic resonator of claim 6, wherein a ratio of a thickness of the lithium tantalate layer over a thickness of the transducer is larger than 10.

10. The acoustic resonator of claim 1, wherein a thickness of the lithium tantalate layer defines a center frequency wavelength (2) of the acoustic resonator.

11. The acoustic resonator of claim 10, wherein the thickness of the lithium tantalate layer is between about 0.1 μm to about 1.1 um.

12. The acoustic resonator of claim 1, wherein the substrate is a quartz substrate.

13. The acoustic resonator of claim 1, further comprising:
an oxide layer disposed over the transducer and in physical contact with the lithium tantalate layer.

14. An acoustic resonator, comprising:
a substrate;
a piezoelectric crystal disposed over the substrate, wherein the piezoelectric crystal has a crystalline orientation defined by a first Euler angle (λ), a second Euler angle (μ), and a third Euler angle (θ), and wherein the second Euler angle (μ) ranges from about −60° to about +30°; and
an interdigital transducer on the piezoelectric crystal.

15. The acoustic resonator of claim 14, wherein the second Euler angle (μ) is between −92° and −72°.

16. The acoustic resonator of claim 14, wherein the piezoelectric crystal is made of lithium tantalate.

17. The acoustic resonator of claim 14, wherein the piezoelectric crystal is made of lithium niobate.

18. The acoustic resonator of claim 14, wherein a thickness of the piezoelectric crystal defines a dominant mode of an acoustic wave excited in the acoustic resonator.

19. The acoustic resonator of claim 18, wherein the dominant mode is an acoustic plate mode (APM).

20. The acoustic resonator of claim 14, wherein a ratio of a pitch of the interdigital transducer over a thickness of the piezoelectric crystal is larger than 10, and a ratio of the thickness of the piezoelectric crystal over a thickness of the interdigital transducer is larger than 10.
